(19) United States
(12) Patent Application Publication
(10) Pub. No.: US 2012/0122311 A1
(43) Pub. Date: May 17, 2012

(54) METAL LAYER FORMATION METHOD FOR DIODE CHIPS/WAFERS

(76) Inventor: Chun-Pin CHEN, (US)

(21) Appl. No.: 13/359,147

(22) Filed: Jan. 26, 2012

Related U.S. Application Data
(63) Continuation-in-part of application No. 11/534,214, filed on Sep. 21, 2006, now abandoned.

(51) Int. Cl. H01L 21/285; H01L 21/288

(52) U.S. Cl. 438/612; 257/E21.161; 257/E21.174

(57) ABSTRACT

An electroless plated metal layer formation method for forming a metal layer on a diode chip/wafer for wire bonding is disclosed to include the step of forming a metal base material on a diode chip/wafer adapted for inducing a reduction system to cause a catalytic reaction at location(s) where the desired metal layer is to be formed, and the step of employing an electroless plating process to form a metal layer on the diode chip/wafer that surrounds the metal base material. An isolation layer may be formed on the metal base layer and opening(s) may be formed on the isolation layer before deposition of the metal layer.

### CROSS REFERENCE TO RELATED ART

This application is a Continuation-In-Part of application Ser. No. 11/534,214, filed on Sep. 21, 2006, now pending. The patent application identified above is incorporated here by reference in its entirety to provide continuity of disclosure.

### BACKGROUND OF THE INVENTION

1. Field of the Invention

The present invention relates to a method of forming a metal layer in a diode structure and more particularly, to an electroless plated metal layer formation method for diode chips/wafers.

2. Description of the Related Art

In light emitting diodes and laser diodes, light is a form of energy that can be released by an atom. It is made up of many photons that are the most basic units of light. Photons are released as a result of moving electrons. In an atom, electrons move in orbitals around the nucleus. Light emitting diodes and laser diodes are found in all kinds of devices in our daily life for the advantages of small size, long life, low driving voltage, low power consumption, and fast reactive speed.

According to conventional manufacturing technology, vapor deposition and sputtering deposition are commonly employed to the fabrication of light emitting diodes and laser diodes. These deposition methods cause deposition of the applied metal target material on the workpiece as well as the inside surface of the peripheral wall of the vacuum chamber, i.e., these deposition methods result in waste of the metal target material and contamination of the vacuum chamber, thereby affecting the quality of the deposited metal layer. In case the so-called double-sided treatment is necessary, the vacuum status of the vacuum chamber must be destroyed and then the wafer must be turned upside down for further deposition, prolonging the manufacturing time.

Therefore, it is desirable to provide an electroless plated metal layer formation method for diode chips/wafers that eliminates the aforesaid drawbacks.

### SUMMARY OF THE INVENTION

The present invention has been accomplished to provide an electroless plated metal layer formation method, which eliminates the aforesaid problems. It is therefore one object of the present invention to provide an electroless plated metal layer formation method, which is practical to form a uniform metal layer on each of two opposite sides of a diode chip or wafer, shortening the manufacturing process and significantly lowering the manufacturing cost.

It is another object of the present invention to provide an electroless plated metal layer formation method, which employs an electroless plating process .to selectively form a metal layer on or around the metal base material instead of whole surface by vapor or sputtering deposition, thereby saving consumption of metal material and electric power and lowering operating and manufacturing cost.

It is still another object of the present invention to provide an electroless plated metal layer formation method, which requires a much lower expense on equipment than vapor deposition or sputtering deposition, thereby saving equipment investment and lower the manufacturing cost.

It is still another object of the present invention to provide an electroless plated metal layer formation method, which is practical to form a metal layer that has a rough surface suitable for wiring bonding or soldering, thereby improving the reliability of the product quality and enhancing the market competitiveness of the product.

It is still another object of the present invention to provide an electroless plated metal layer formation method, which is practical to form a metal layer suitable for forming metal bumps, metal pads, metal wires or heat plate, or for the purposes of wire bonding, soldering, or flip-chip package, enhancing heat dissipation effects and improving product quality and reliability.

To achieve these and other objects of the present invention, the electroless plated metal layer formation method includes the steps of: (a): providing a diode chip/wafer; (b): forming on the diode chip/wafer at least one predetermined location a patterned metal base material, and then employing a plasma treatment to the diode chip/wafer, and then dipping the diode chip/wafer in a surfactant solution to wet the surface of the patterned metal base material; and (c): employing an electroless metal reduction wet process to form a metal layer on the diode chip/wafer that surrounds the border of the patterned metal base material on the diode chip/wafer at each of the at least one predetermined location and then dipping the diode chip/wafer in a cleaning solution (surfactant solution or clean water) to remove residual chemicals.

According to an alternate form of the present invention, the electroless metal layer formation method includes the steps of: (a): providing a diode chip/wafer; (b): forming on the diode chip/wafer at predetermined locations a patterned metal base material; (c): forming on the diode chip/wafer an isolation layer over the patterned metal base material; (d): forming openings on the isolation layer subject to a predetermined pattern to have the patterned metal base material be exposed to the outside, and then employing a plasma treatment to the diode chip/wafer, and then dipping the diode chip/wafer in a surfactant solution to wet the surface of the patterned metal base material; and (e): employing an electroless plating process to deposit a metal layer on the patterned metal base material corresponding to the openings and then dipping the diode chip/wafer in a cleaning solution (surfactant solution or clean water) to remove residual chemicals.

### BRIEF DESCRIPTION OF THE DRAWINGS

FIG. 1 is a schematic drawing of a finished product obtained according to one embodiment of the present invention.

FIG. 2 is a flow chart illustrating the fabrication of the finished product shown in FIG. 1.

FIG. 3 is a schematic drawing of a finished product obtained according to another embodiment of the present invention.

FIG. 4 is a schematic drawing of a finished product obtained according to still another embodiment of the present invention.

FIG. 5 is a flow chart showing the fabrication of the finished product shown in FIG. 4.

FIG. 6 is a schematic drawing of a finished product obtained according to still another embodiment of the present invention.

FIG. 7 is a schematic drawing of a finished product obtained according to still another embodiment of the present invention.

FIG. 8 is a flow chart showing the fabrication of the finished product shown in FIG. 7.

FIG. 9 is a schematic drawing of a finished product obtained according to still another embodiment of the present invention.

FIG. 10 is a schematic drawing of a finished product obtained according to still another embodiment of the present invention.

FIG. 11 is a flow chart showing the fabrication of the finished product shown in FIG. 10.

FIG. 12 is a schematic drawing of a finished product obtained according to still another embodiment of the present invention.

FIG. 13 is a flow chart showing the fabrication of the finished product shown in FIG. 12.

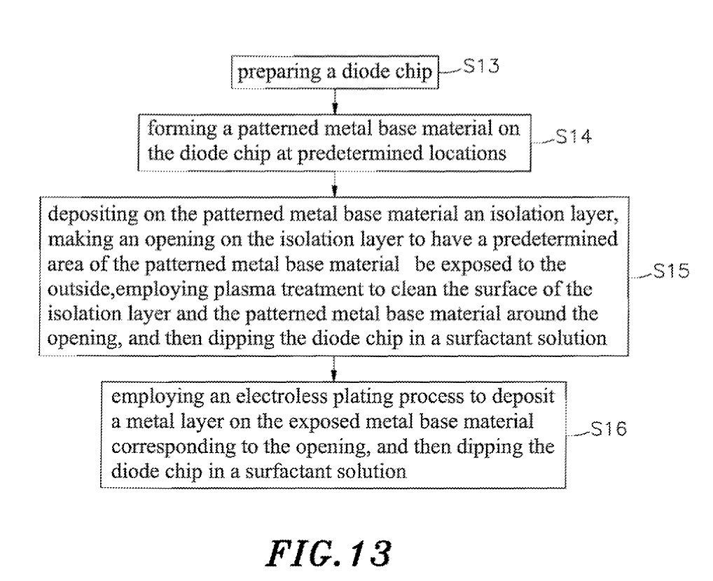

FIG. 14 is a schematic drawing of a finished product obtained according to still another embodiment of the present invention.

FIG. 15 is a schematic drawing of a finished product obtained according to still another embodiment of the present invention.

FIG. 16 is a schematic drawing of a finished product according to still another embodiment of the present invention.

FIG. 17 is a schematic drawing of a finished product obtained according to still another embodiment of the present invention.

### DETAILED DESCRIPTION OF THE PREFERRED EMBODIMENT

The invention relates to an electroless plated metal layer formation method for diode chips/wafers. The metal layer indicated herein can be metal bumps, metal pads, or a heat plate for wire bonding, solder bonding, conducting, flip-chip package, and many other purposes. Any products using the electroless plated metal layer formation method for diode chips/wafers should be included in the scope of the present invention.

First of all, the invention uses an electroless plating process to match with a metal base material for inducing a reduction system to cause a catalytic reaction, thereby forming a uniform metal layer having the desired thickness. A metal layer made according to the present invention can be thicker than 0.1 μm. The material for the metal layer can be gold, nickel, copper, platinum, palladium, zinc, tin, silver or chrome, or their bimetal. The material for the metal base layer can also be gold, nickel, copper, platinum, palladium, zinc, tin, silver or chrome, or their bimetal. The metal base material can be formed by means of vapor deposition, electroplating, sputtering deposition, or electroless plating. In case gold is used for the metal layer, the electroless plating process is employed with a reacting solution containing a metal salt obtained from gold cyanide, sulfite gold, or gold trichloride.

The metal layer formed by means of the application of an electroless plating process according to the present invention may surround the metal base material. When wishing to limit the metal layer to specific locations on the metal base layer, an isolation layer is formed by means of the application of an dielectric material such as SᵢO₂, photoresist, or PI, and then openings are formed on the isolation layer subject to the desired locations, and then plasmas treatment is employed to the device thus obtained, and then the device is dipped in a surfactant solution to wet the surface of the metal base material, and then an electroless plating process is employed to deposit the desired metal layer on the metal base layer in the openings of the isolation layer. After formation of the metal layer, the isolation layer may be removed, and then the device is dipped in a cleaning solution to remove residual chemicals.

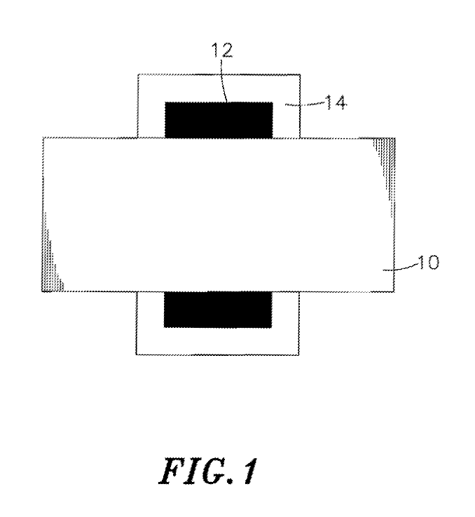

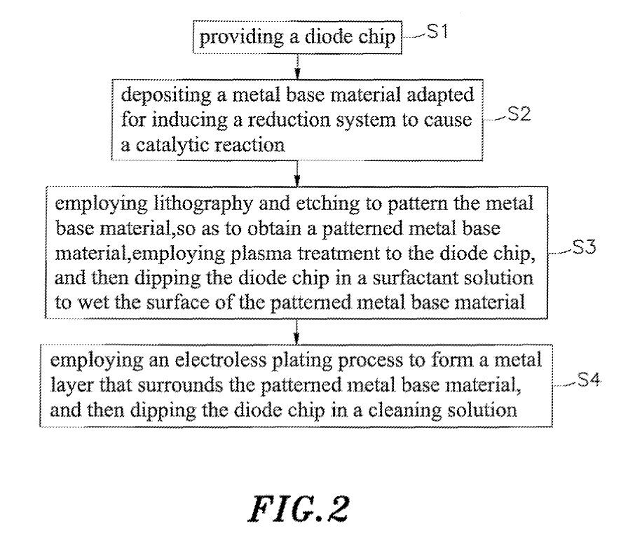

Referring to FIGS. 1 and 2, an electroless plated metal layer formation method for diode chips/wafers in accordance with a first embodiment of the present invention includes the steps of:

S1: providing a diode chip (or wafer) 10;

S2: forming on each of two opposite sides of the diode chip (or wafer) 10 a metal base material 12 adapted for inducing a reduction system to cause a catalytic reaction;

S3: employing lithography and etching technology to pattern the metal base material on each of the two opposite sides of the diode chip 10 to obtain a patterned metal base material 12, and then employing plasma treatment to the diode chip (or wafer) 10, and then dipping the diode chip (or wafer) 10 in a surfactant solution to wet the surface of the patterned metal base material 12; and

S4: employing an electroless plating process to form a metal layer 14 that surrounds the border of the patterned metal base material 12 on each of the two opposite sides of the diode chip (or wafer) 10, and then dipping the diode chip (or wafer) 10 in a cleaning solution (surfactant solution or clean water) to remove residual chemicals from the metal layer 14.

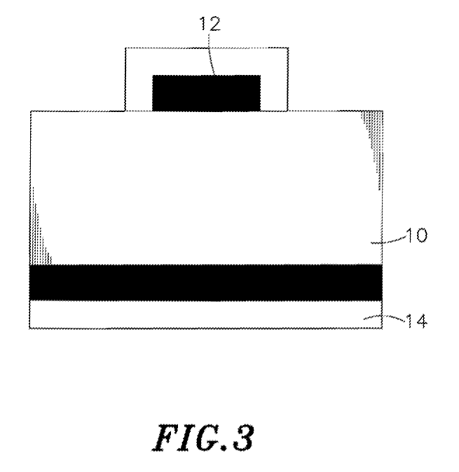

FIG. 3 is a schematic drawing of a finished product obtained according to a second embodiment of the present invention. This second embodiment is substantially similar to the aforesaid first embodiment with the exception that this second embodiment has only patterned the metal base material 12 on one side of the diode chip.

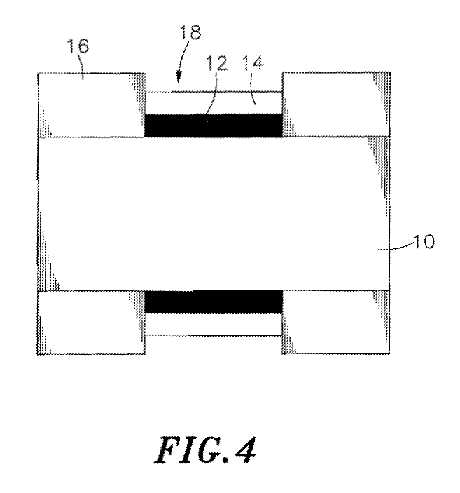

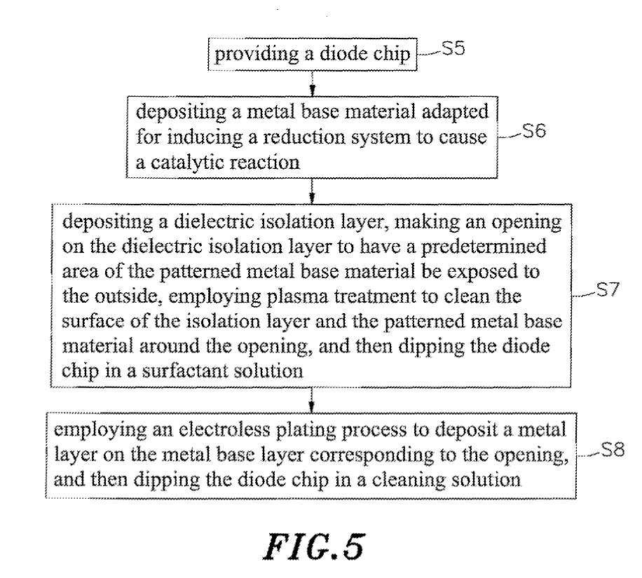

FIG. 4 is a schematic drawing of a finished product obtained according to a third embodiment of the present invention. FIG. 5 is a flow chart of the third embodiment shown in FIG. 4. According to this third embodiment, the electroless plated metal layer formation method includes the steps of:

S5: providing a diode chip (or wafer) 10;

S6: forming on each of two opposite sides of the diode chip (or wafer) 10 a patterned metal base material 12 adapted for inducing a reduction system to cause a catalytic reaction;

S7: depositing on the patterned metal base material 12 on each of the two opposite sides of the diode chip (or wafer) 10 an isolation layer 16 by means of the application of an dielectric material such as SᵢO₂, photoresist, or PI, and then making an opening 18 on the isolation layer 16 on the patterned metal base material 12 on each of the two opposite sides of the diode chip (or wafer) 10 to have a predetermined area of the patterned metal base material 12 be exposed to the outside, and then employing plasma treatment (argon, oxygen, nitrogen, or their mixture) to clean the surface of the isolation layer 16 and the patterned metal base material 12 around the opening. 18, and then dipping the diode chip (or wafer) 10 in a surfactant solution (anion surfactant solution, cation surfactant solution, nonionic surfactant solution, or organic acid, inorganic acid or salt-based liquefied pH regulating solution) to wet the surface of the patterned metal base material 12; and

S8: employing an electroless plating process to form a metal layer 14 on the exposed predetermined area of the patterned metal base material 12 in the associating opening 18 on each of the two opposite sides of the diode chip (wafer) 10, and then dipping the diode chip (or wafer) 10 in a cleaning solution (surfactant solution such as anion surfactant solution, cation surfactant solution, nonionic surfactant solution, or organic acid, inorganic acid or salt-based liquefied pH regulating solution) to remove residual chemicals.

The aforesaid plasma treatment is to clean the surface of the isolation layer 16 and the patterned metal base material 12 around the opening 18 with the ion source (argon, oxygen, nitrogen, or their mixture) of the applied plasma under a rough vacuum status by means of bombing or oxidation, removing external objects (such as: organic substances) from the patterned metal base material 12 and improving integrity and flatness of succeeding coating layer. The applied surfactant solution (anion surfactant solution, cation surfactant solution, nonionic surfactant solution, or organic acid, inorganic acid or salt-based liquefied pH regulating solution) prevents residual bubbles on the surface of the patterned metal base material 12 and ensures uniform contact between the patterned metal base material 12 and the applied chemical plating solution to form an integrated, uniform thickness of coating on the surfaces of the patterned metal base material in the succeeding chemical plating process. After formation of the integrated coating, a surfactant solution (anion surfactant solution, cation surfactant solution, nonionic surfactant solution, or organic acid, inorganic acid or salt-based liquefied pH regulating solution) or water is used to clean the patterned metal base material 12, removing residual chemicals.

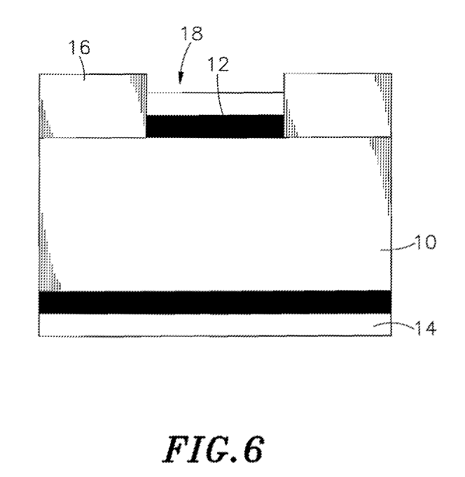

FIG. 6 is a schematic drawing of a finished product obtained according to a fourth embodiment of the present invention. This fourth embodiment is substantially similar to the aforesaid third embodiment with the exception that this fifth embodiment only deposits an isolation layer 16 on the patterned metal base material 12 on one side of the diode chip (or wafer) 10.

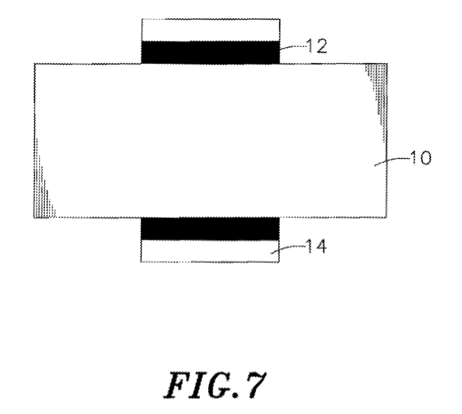

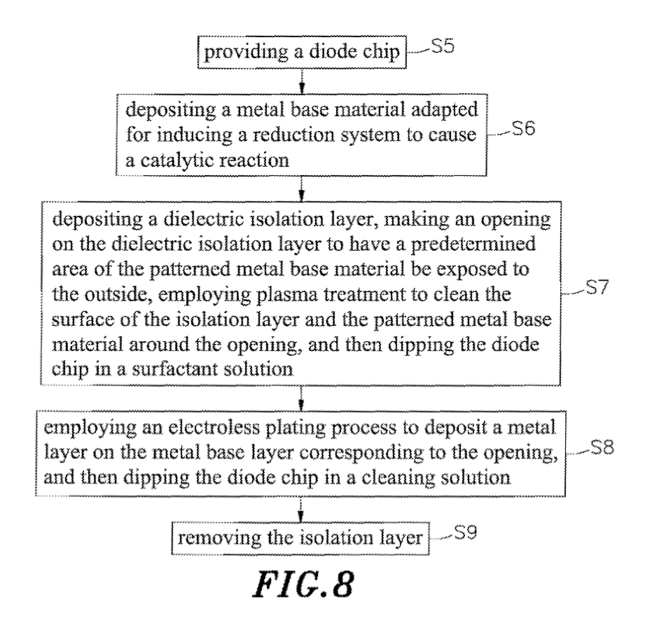

FIG. 7 is a schematic drawing of a finished product obtained according to a fifth embodiment of the present invention. FIG. 8 is a flow chart of the fifth embodiment of the present invention. This fifth embodiment is substantially similar to that shown in FIG. 5 with the exception of an extra step S9. Step S9 is employed, after step S8, to remove the isolation layer 16 from each of the two opposite sides of the diode chip.

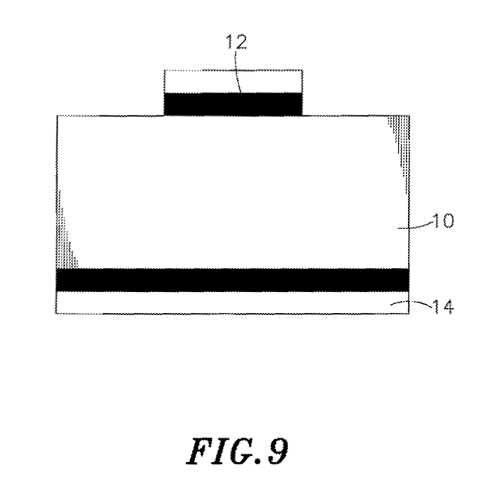

FIG. 9 is a schematic drawing of a finished product obtained according to a sixth embodiment of the present invention, which is a structure obtained after removal of the isolation layer 16 from the aforesaid fourth embodiment shown in FIG. 6.

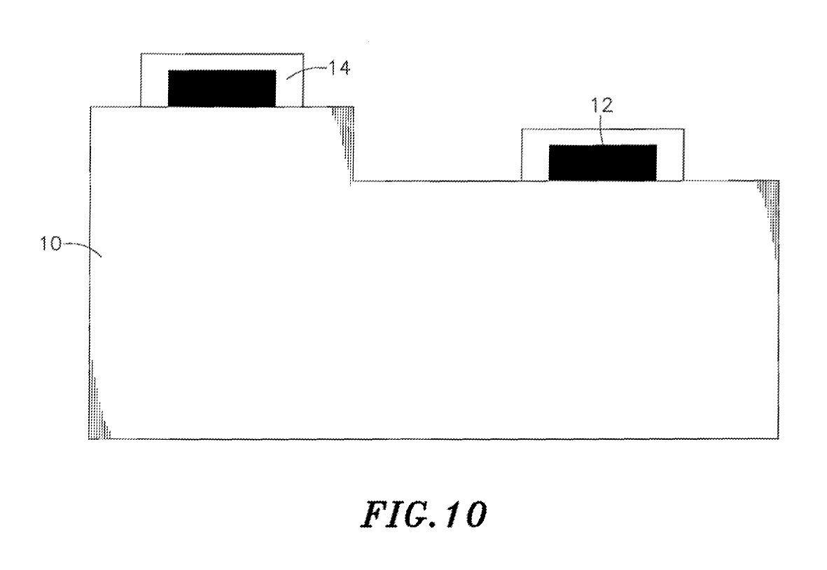

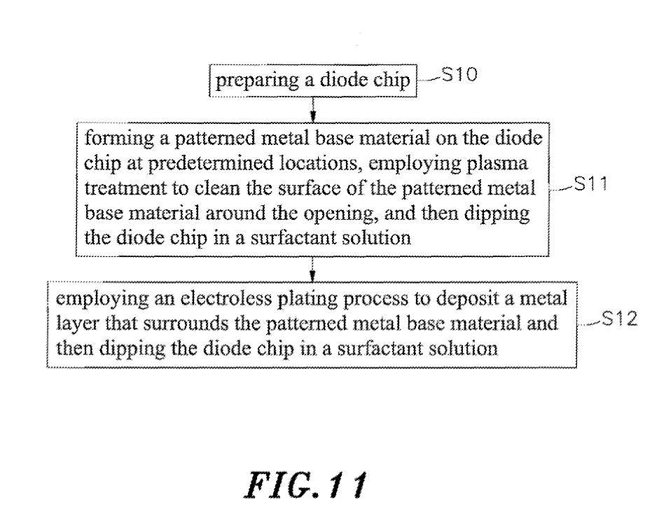

FIG. 10 is a schematic drawing of a finished product obtained according to a finished product obtained according to a seventh embodiment of the present invention. FIG. 11 is a flow chart of the seventh embodiment shown in FIG. 10. According to this seventh embodiment, the electroless plated metal layer formation method includes the steps of:

S10: preparing a diode chip (or wafer) 10 having electrodes arranged on the same side at different elevations;

S11: forming a patterned metal base material 12 on the diode chip (or wafer) 10 at predetermined locations, and then employing plasma treatment (argon, oxygen, nitrogen, or their mixture) to clean the surface of the patterned metal base material 12 around the opening 18, and then dipping the diode chip (or wafer) 10 in a surfactant solution (anion surfactant solution, cation surfactant solution, nonionic surfactant solution, or organic acid, inorganic acid or salt-based liquefied pH regulating solution) to wet the surface of the patterned metal base material 12;

S12: employing an electroless plating process to form a metal layer 14 that surrounds the border of the patterned metal base material 12 at each of the predetermined locations on the diode chip (wafer) 10, and then dipping the diode chip (or wafer) 10 in a surfactant solution (anion surfactant solution, cation surfactant solution, nonionic surfactant solution, or organic acid, inorganic acid or salt-based liquefied pH regulating solution) to remove residual chemicals.

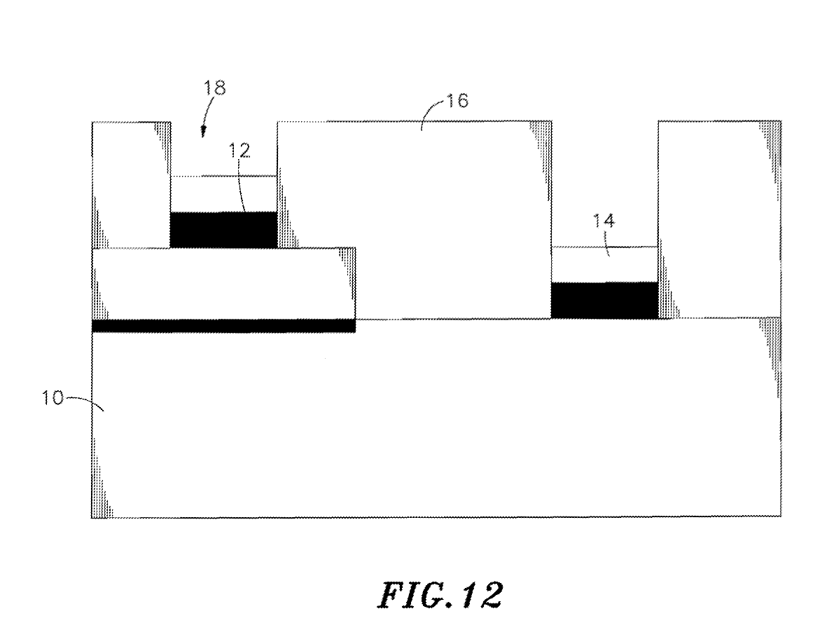

FIG. 12 is a schematic drawing of a finished product obtained according to an eighth embodiment of the present invention. This embodiment employs to a diode chip having electrodes arranged on the same side at different elevations the concept of using an isolation layer to limit the deposition location of the metal layer on the metal base material as see in the aforesaid third embodiment of the present invention. FIG. 11 is a flow chart of the seventh embodiment shown in FIG. 10. According to this eighth embodiment, the electroless plated metal layer formation method includes the steps of:

S13: preparing a diode chip (or wafer) 10 having electrodes arranged on the same side at different elevations;

S14: forming a patterned metal base material 12 on the diode chip (or wafer) 10 at predetermined locations;

S15: depositing on the patterned metal base material 12 on the diode chip (or wafer) 10 an isolation layer 16 by means of the application of an dielectric material such as SᵢO₂, photoresist, or PI, and then making an opening 18 on the isolation layer 16 to have a predetermined area of the patterned metal base material 12 be exposed to the outside, and then employing plasma treatment (argon, oxygen, nitrogen, or their mixture) to clean the surface of the isolation layer 16 and the patterned metal base material 12 around the opening 18, and then dipping the diode chip (or wafer) 10 in a surfactant solution (anion surfactant solution, cation surfactant solution, nonionic surfactant solution, or organic acid, inorganic acid or salt-based liquefied pH regulating solution) to wet the surface of the patterned metal base material 12; and

S16: employing an electroless plating process to form a metal layer 14 on the exposed predetermined area of the patterned metal base material 12 corresponding to the opening 18, and then dipping the diode chip (or wafer) 10 in a surfactant solution (anion surfactant solution, cation surfactant solution, nonionic surfactant solution, or organic acid, inorganic acid or salt-based liquefied pH regulating solution) to remove residual chemicals.

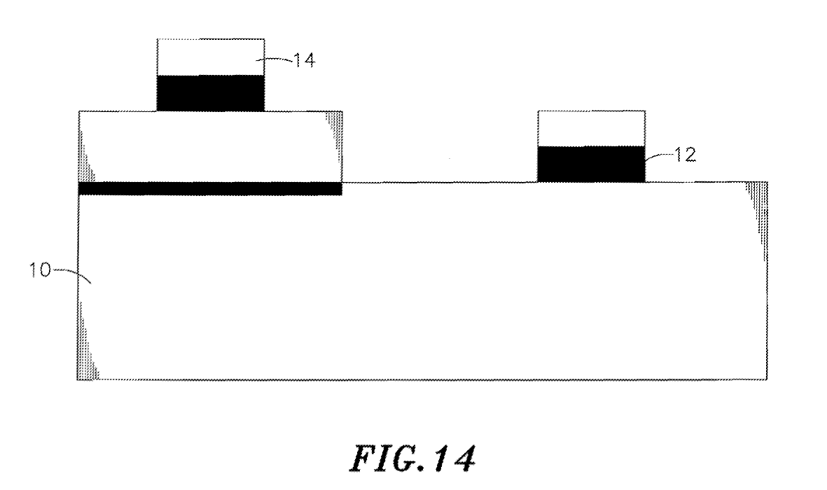

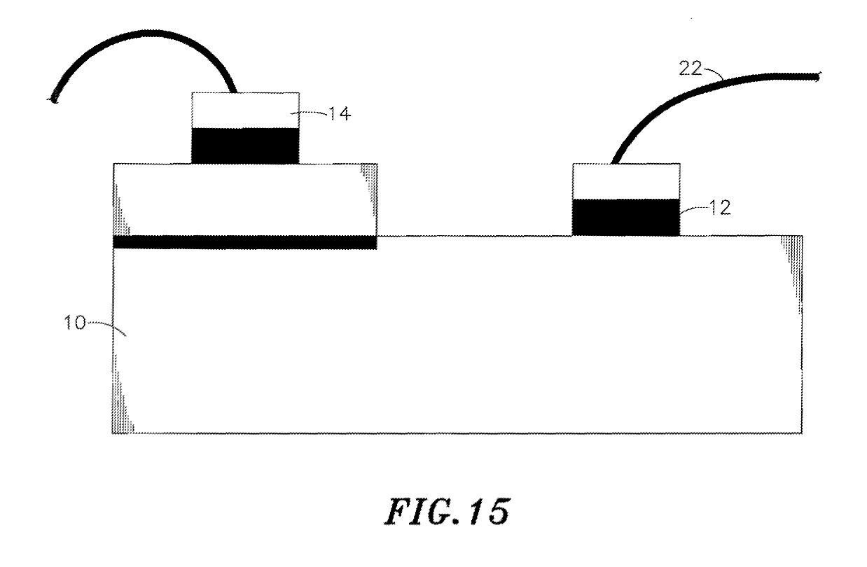

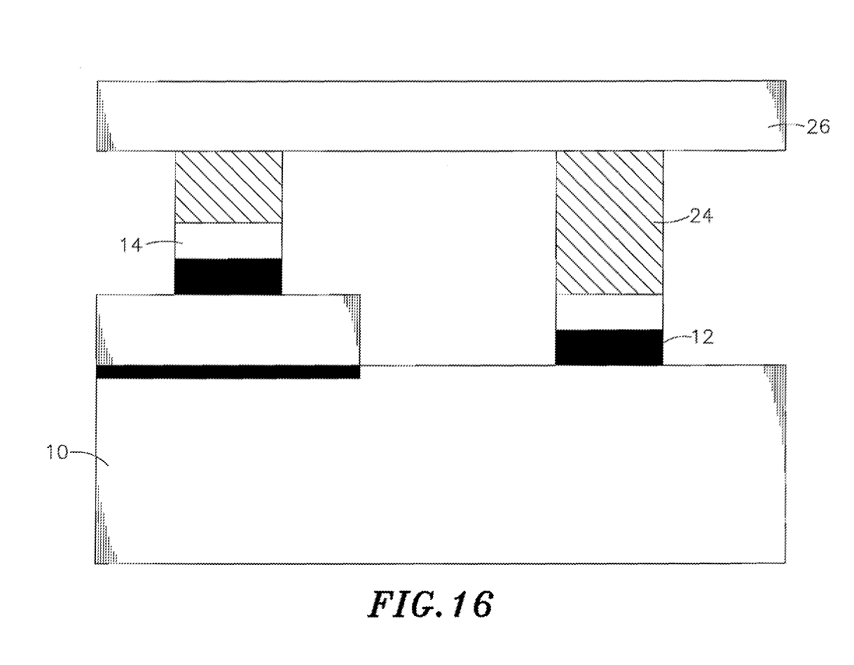

FIG. 14 is a schematic drawing of a finished product obtained according to a ninth embodiment of the present invention. This embodiment is obtained from the structure of the aforesaid eighth embodiment by removing the isolation layer 16 after formation of the metal layer 14. Thereafter, metal wires 22 may be bonded to the metal layer 14 as shown in FIG. 15. Alternatively, a bonding layer 24 may be formed on the metal layer 14 for the bonding of a carrier plate 26 as shown in FIG. 16.

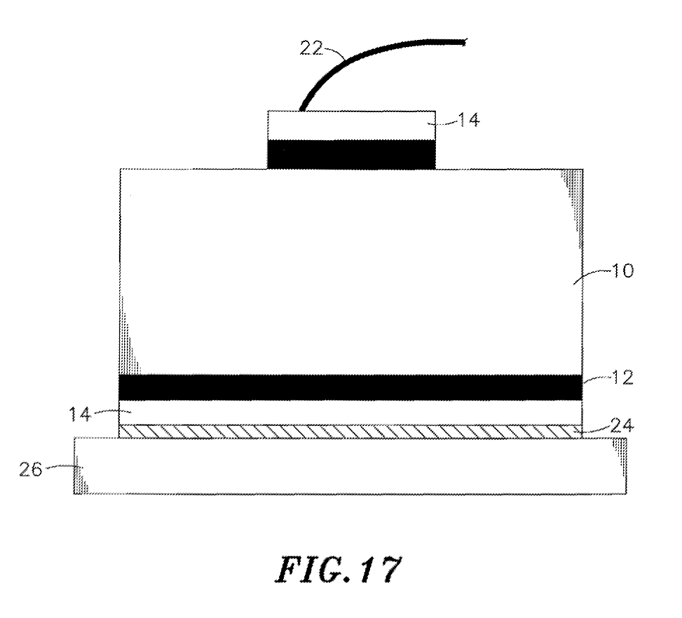

FIG. 17 is a schematic drawing of a finished product obtained according to a tenth embodiment of the present invention. This embodiment has a diode chip that has a metal layer formed by means of the application of an electroless plating process according to the present invention, which may be mounted with a chip or carrier plate and bonded with metal wires. The exemplar shown in FIG. 17 is based on the sixth embodiment of the present invention. As illustrated, one metal layer 14 at one side of the finished product of the aforesaid sixth embodiment of the present invention is bonded to a chip or carrier plate 26 with a bonding layer 24, and a metal wire 22 is bonded to the other metal layer 14.

As indicated above, the invention provides an electroless plated metal layer formation method for diode chips/wafers. The invention sues an electroless plating process to match with a metal base material for inducing a reduction system (reacting solution added with a metal substance) to cause a catalytic reaction, thereby forming a uniform metal layer having the desired thickness. This method is practical to deposit a metal layer on one or both sides of the diode chip/wafer, eliminating the step of turning the diode chip/wafer to the other side as used in the prior art methods. The manufacturing process of the present invention is practical to form a metal layer of high uniformity. The operation of the present invention is easy, therefore the invention greatly shortens the manufacturing time, and lowers the manufacturing cost. A metal layer made according to the present invention has a surface rougher than a metal layer made by vapor deposition or sputtering deposition, and is practical for wire bonding or soldering, thereby improving the reliability of the product quality and enhancing the market competitiveness of the product.

A prototype of electroless plated metal layer formation method for diode chips/wafers has been constructed with the features of FIGS. 1˜17. The electroless plated metal layer formation method for diode chips/wafers functions smoothly to provide all of the features disclosed earlier.

Although particular embodiment of the invention have been described in detail for purposes of illustration, various modifications and enhancements may be made without departing from the spirit and scope of the invention. Accordingly, the invention is not to be limited except as by the appended claims.

What the invention claimed is:

1. An electroless plated metal layer formation method comprising the steps of:
(a): providing a diode chip/wafer;
(b): forming on said diode chip/wafer at predetermined locations a patterned metal base material;
(c): forming on said diode chip/wafer an isolation layer over said patterned metal base material;
(d): forming openings on said isolation layer subject to a predetermined pattern to have said patterned metal base material be exposed to the outside, and then employing a plasma treatment to said diode chip/wafer, and then dipping said diode chip/wafer in a surfactant solution to wet the surface of said patterned metal base material; and
(e): employing an electroless plating process to deposit a metal layer on said patterned metal base material corresponding to said openings and then dipping said diode chip/wafer in a cleaning solution to remove residual chemicals.

2. The electroless plated metal layer formation method as claimed in claim 1, further comprising the step of removing said isolation layer after deposition of said metal layer.

3. The electroless plated metal layer formation method as claimed in claim 1, wherein said metal base material is obtained from one of the metal materials including gold, nickel, copper, platinum, palladium, zinc, tin, silver, and chrome.

4. The electroless plated metal layer formation method as claimed in claim 1, wherein said metal layer is obtained from one of the metal materials including gold, nickel, copper, platinum, palladium, zinc, tin, silver, and chrome.

5. The electroless plated metal layer formation method as claimed in claim 1, wherein said metal base material is formed by means of the application of one of the methods including vapor deposition, electroplating, sputtering deposition, and electroless plating.

6. The electroless plated metal layer formation method as claimed in claim 1, wherein said metal layer is adapted for forming metal bumps, metal pads, or metal wires.

7. The electroless plated metal layer formation method as claimed in claim 1, further comprising the step of bonding metal wires to said metal layer.

8. The electroless plated metal layer formation method as claimed in claim 1, further comprising the step of forming a conducting bonding layer on said metal layer for flip-chip package.

9. The electroless plated metal layer formation method as claimed in claim 1, wherein said metal layer is obtained from gold, and said electroless plating process is employed with a reacting solution containing a metal salt obtained from gold cyanide, sulfite gold, gold trichloride.

10. The electroless plated metal layer formation method as claimed in claim 1, wherein said plasma treatment uses an ion source selected from the group of argon, oxygen, nitrogen and their mixtures for cleaning the surface of said diode chip/wafer around said openings.

11. The electroless plated metal layer formation method as claimed in claim 1, wherein said surfactant solution is selected from the group of anion surfactant solution, cation surfactant solution, nonionic surfactant solution, and organic acid, inorganic acid and salt-based liquefied pH regulating solutions.

12. The electroless plated metal layer formation method as claimed in claim 1, wherein said cleaning solution is selected from the group of surfactant solution and water.
